(19) United States
(12) Patent Application Publication
(10) Pub. No.: US 2005/0130372 A1
(43) Pub. Date: Jun. 16, 2005

(54) Method for manufacturing flash memory device

(75) Inventor: Dong Kee Lee, Kyungki-Do (KR)

Correspondence Address: MARSHALL, GERSTEIN & BORUN LLP, 6300 SEARS TOWER, 233 S. WACKER DRIVE, CHICAGO, IL, 60606, US

(73) Assignee: HYNIX SEMICONDUCTOR INC., Kyungki-Do (KR)

(21) Appl. No.: 10/878,916

(22) Filed: Jun. 28, 2004

(30) Foreign Application Priority Data
Dec. 15, 2003 (KR) 2003-91653

(51) Int. Cl. H01L 21/336; H01L 21/8234; H01L 29/00

(52) U.S. Cl. 438/257; 438/275

(57) ABSTRACT

The present invention discloses a method for manufacturing a flash memory device, including the steps of: forming gate electrode patterns on a semiconductor substrate on which a high voltage region and a low voltage region are defined; forming a first mask pattern for simultaneously exposing the high voltage region and the low voltage region, and forming junction regions in the high voltage region and the low voltage region at the same time by performing a first ion implant process; removing the first mask pattern for simultaneously exposing the high voltage region and the low voltage region, and forming spacers on each gate electrode pattern; forming a second mask pattern for simultaneously exposing the high voltage region and the low voltage region; and forming LDD regions in the junction region of the high voltage region and the junction region of the low voltage region at the same time by performing a second ion implant process.

### BACKGROUND

1. Field of the Invention

The present invention relates to a method for manufacturing a flash memory device, and more particularly to, a method for manufacturing a flash memory device including a low voltage region and a high voltage region.

2. Discussion of Related Art

FIGS. 1 to 4 are cross-sectional diagrams illustrating sequential steps of a conventional method for manufacturing a flash memory device. The conventional method for manufacturing the flash memory device will now be described with reference to FIGS. 1 to 4.

Referring to FIG. 1, an element isolation film 12 and gate electrode patterns 14 are formed on a semiconductor substrate 10. A low voltage region (LVR) and a high voltage region (HVR) are defined on the semiconductor substrate 10.

A photoresist pattern (not shown) is formed and masked in the LVR of the semiconductor substrate 10. A first junction region 16 is formed in the exposed HVR by an ion implant process.

As shown in FIG. 2, the photoresist pattern formed in the LVR is removed, and a photoresist pattern (not shown) is formed and masked in the HVR. Thereafter, a second junction region 18 is formed in the exposed LVR by an ion implant process. Finally, the photoresist pattern formed in the HVR is removed.

As depicted in FIG. 3, spacers 20 are formed on the sidewalls of the gate electrode patterns 14 in the HVR and the LVR. A photoresist pattern is formed and masked in the HVR, and a lightly doped drain (LDD) region 22 is formed in the second junction region 18 of the LVR by an ion implant process using the exposed gate electrode pattern 14 and spacer 20 in the LVR as an ion implant mask.

As illustrated in FIG. 4, an interlayer insulation film 24 is formed on the whole surface of the resulting structure, and contact holes are formed to expose predetermined regions of each junction region 16 and 18 formed in the HVR and the LVR. A photoresist pattern is formed to expose the contact hole formed in the HVR. When an ion implant process is performed on the resulting structure, ions are implanted merely to the exposed first junction region 16 in the HVR.

Contact plugs 28 are formed in the LVR and the HVR, respectively, by forming a metal material on the resulting structure, thereby finishing the whole process.

The conventional process for forming the junction regions of the flash memory device forms the junction regions in the HVR and the LVR, respectively, and thus increases the number of masking processes. Accordingly, the number of process steps increases.

### SUMMARY OF THE INVENTION

The present invention is directed to a method for manufacturing a flash memory device which can reduce the number of process steps.

One aspect of the present invention is to provide a method for manufacturing a flash memory device, including the steps of: forming gate electrode patterns on a semiconductor substrate on which a high voltage region and a low voltage region are defined; forming a first mask pattern for simultaneously exposing the high voltage region and the low voltage region, and forming junction regions in the high voltage region and the low voltage region at the same time by performing a first ion implant process; removing the first mask pattern for simultaneously exposing the high voltage region and the low voltage region, and forming spacers on each gate electrode pattern; forming a second mask pattern for simultaneously exposing the high voltage region and the low voltage region; and forming LDD regions in the junction region of the high voltage region and the junction region of the low voltage region at the same time by performing a second ion implant process.

Preferably, the first ion implant process performs a P ion implant process and an As ion implant process, respectively.

Preferably, the second ion implant process performs an As ion implant process.

Another aspect of the present invention is to provide a method for manufacturing a flash memory device, comprising the steps of: forming gate electrode patterns on a semiconductor substrate on which a high voltage region and a low voltage region are defined; forming a first mask pattern for simultaneously exposing the high voltage region and the low voltage region, and forming junction regions in the high voltage region and the low voltage region at the same time by performing a first ion implant process; removing the first mask pattern for simultaneously exposing the high voltage region and the low voltage region, and forming spacers on each gate electrode pattern; forming a second mask pattern for simultaneously exposing the high voltage region and the low voltage region; and forming LDD regions in the junction region of the high voltage region and the junction region of the low voltage region at the same time by performing a second ion implant process; forming an interlayer insulation film on the whole surface of the resulting structure; and forming contact plugs contacting the LDD regions of the high voltage region and the low voltage region.

### BRIEF DESCRIPTION OF THE DRAWINGS

FIGS. 1 to 4 are cross-sectional diagrams illustrating sequential steps of a conventional method for manufacturing a flash memory device;

FIGS. 5 to 7 are cross-sectional diagrams illustrating sequential steps of a method for manufacturing a flash memory device in accordance with the present invention; and

FIG. 8 is a table showing junction region characteristics in the conventional art and the present invention.

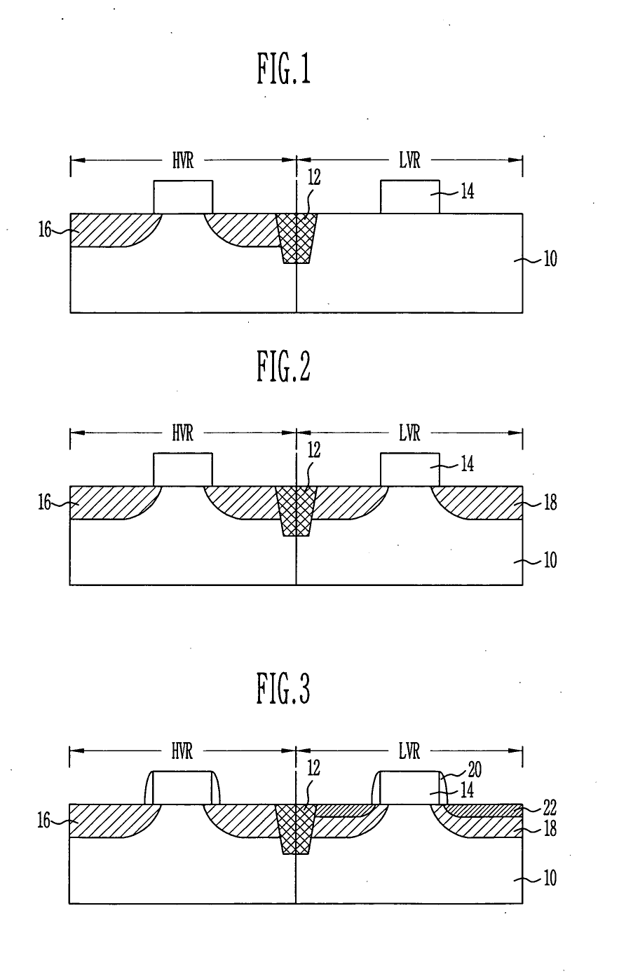

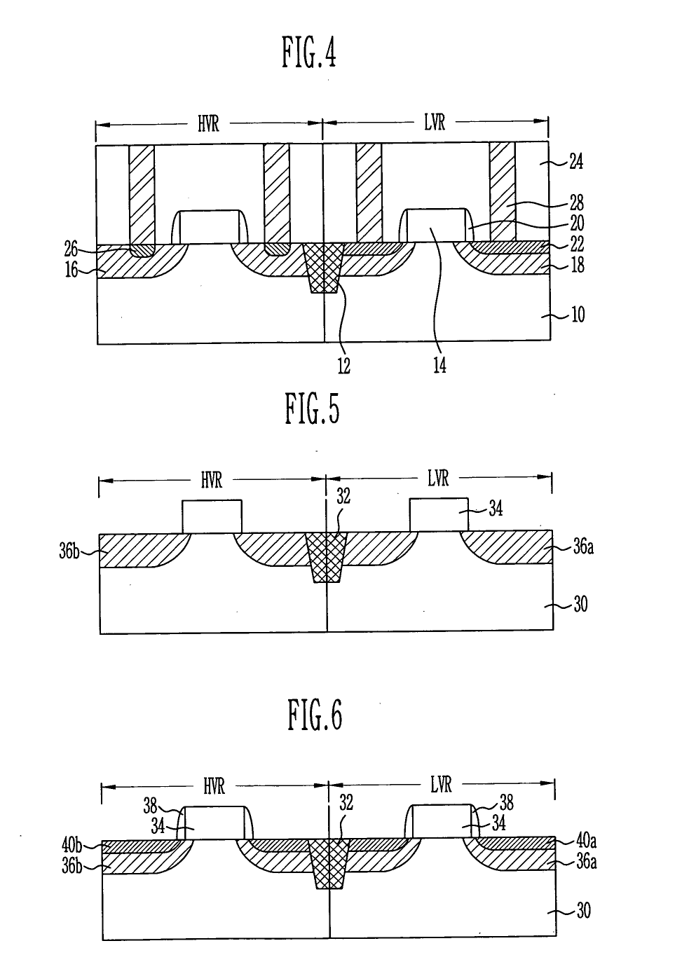

### DETAILED DESCRIPTION OF PREFERRED EMBODIMENTS

A method for manufacturing a flash memory device in accordance with a preferred embodiment of the present invention will now be described in detail with reference to the accompanying drawings. Wherever possible, the same reference numerals will be used throughout the drawings and the description to refer to the same or like parts. In case it is described that one film is disposed on or contacts another film or a semiconductor substrate, one film can directly contact another film or the semiconductor substrate, or the third film can be positioned between them.

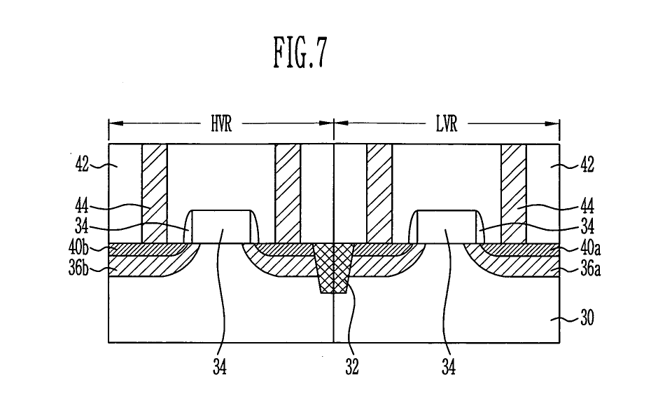

FIGS. 5 to 7 are cross-sectional diagrams illustrating sequential steps of the method for manufacturing the flash memory device in accordance with the present invention.

As illustrated in FIG. 5, an element isolation film 32 and gate electrode patterns 34 are formed in predetermined regions of a semiconductor substrate 30.

The element isolation film 32 can be formed by an STI process, and the gate electrode patterns 34 can be formed by sequentially forming and patterning a gate oxide film and a polysilicon film for a gate electrode.

A low voltage region (LVR) and a high voltage region (HVR) are defined on the semiconductor substrate 30.

A photoresist pattern (not shown) is formed to simultaneously expose the HVR and the LVR of the semiconductor substrate 30. A junction region 36b and a junction region 36a are respectively formed in the HVR and the LVR by an ion implant process using the photoresist pattern (not shown) and the gate electrode patterns 34 as an ion implant mask.

The junction region 36b and the junction region 36a are formed in the HVR and the LVR at the same time by one ion implant process. In the conventional art, the junction regions are formed in each region by a plurality of processes, such as masking the HVR, forming the junction region merely in the LVR by the ion implant process, masking the LVR, and forming the junction region merely in the HVR by the ion implant process. Conversely, in accordance with the present invention, the junction regions are formed in each region by one ion implant process, by simultaneously exposing the HVR and the LVR, thereby reducing a number of process steps.

On the other hand, ions implanted during the ion implant process are P and As. Here, P and As are implanted by each ion implant process.

An effective gate length increases due to the junction regions formed by the two ion implant processes. Therefore, a length of the gate electrode can be reduced.

As shown in FIG. 6, the photoresist pattern (not shown) exposing the HVR and the LVR of the resulting structure is removed, and spacers 38 are formed on the sidewalls of the gate electrode patterns 34 formed in the HVR and the LVR.

An LDD region 40b and an LDD region 40a are respectively formed in the junction region 36b of the HVR and the junction region 36a of the LVR at the same time by an ion implant process using the spacers 38 and the gate electrode patterns 34 as an ion implant mask.

Identically to the junction region 36b of the HVR and the junction region 36a of the LVR, the LDD region 40b and the LDD region 40a are formed in the HVR and the LVR at the same time.

Ions implanted during the ion implant process are As.

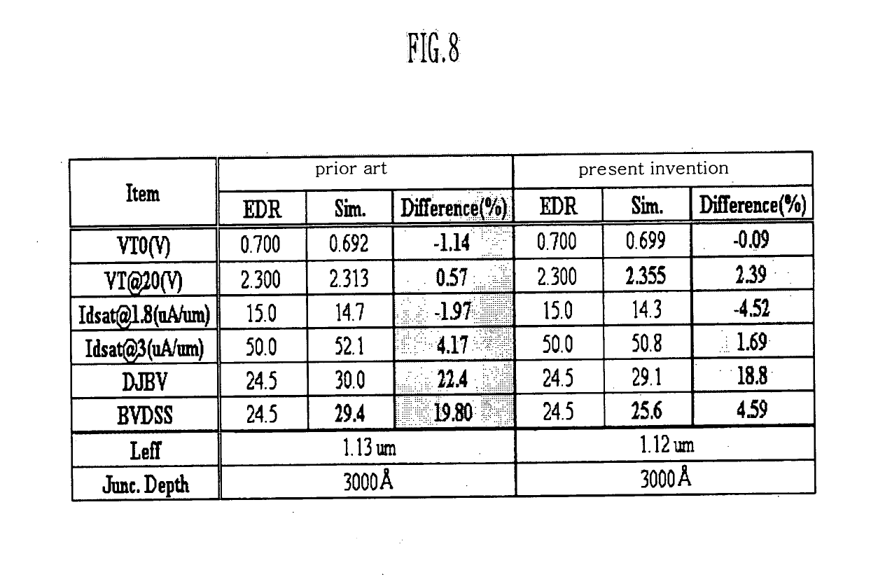

As depicted in FIG. 7, an interlayer insulation film 42 is formed on the whole surface of the resulting structure where the LDD region 40b and the LDD region 40a have been formed, and patterned to expose the LDD regions 40a and 40b, to form contact holes. Contact plugs 44 are formed by filling a conductive material in the contact holes, thereby finishing the whole process.

In the conventional art, the concentration of the junction regions is prevented from being reduced after forming the contact holes, by exposing the contact hole in the HVR and implanting ions into the first junction region 16. However, in accordance with the present invention, the concentration of the junction regions is prevented from being reduced after forming the contact holes, by simultaneously exposing the HVR and the LVR and forming the LDD regions in each region, without requiring additional masking processes.

FIG. 8 is a table showing junction region characteristics in the conventional art and the present invention.

Referring to FIG. 8, EDR denotes a characteristic reference value in the junction region, and a simulation result (Sim) denotes a measured value in the junction region. FIG. 8 also shows differences of the EDR and simulation results in the conventional art and the present invention.

The difference range of the conventional art and the difference range of the present invention are not large, and thus the junction region characteristics of the present invention are deemed to be similar to those of the conventional art. That is, the junction regions of the present invention are formed by the smaller number of process steps than those of the conventional art, and have similar characteristics to those of the junction regions of the conventional art.

In accordance with the present invention, the number of the process steps can be reduced by simultaneously forming the junction regions in the HVR and the LVR.

As described earlier, in accordance with the present invention, the method for manufacturing the flash memory device can reduce the number of the process steps by simultaneously forming the junction regions in the HVR and the LVR.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

1. A method for manufacturing a flash memory device, comprising the steps of:
forming gate electrode patterns on a semiconductor substrate on which a high voltage region and a low voltage region are defined;
forming a first mask pattern for simultaneously exposing the high voltage region and the low voltage region, and forming junction regions in the high voltage region and the low voltage region at the same time by performing a first ion implant process;
removing the first mask pattern for simultaneously exposing the high voltage region and the low voltage region, and forming spacers on each gate electrode pattern;
forming a second mask pattern for simultaneously exposing the high voltage region and the low voltage region; and
forming LDD regions in the junction region of the high voltage region and the junction region of the low voltage region at the same time by performing a second ion implant process.

2. The method of claim 1, after the step of forming the LDD regions, further comprising the steps of:
forming an interlayer insulation film on the whole surface of the resulting structure; and
forming contact plugs contacting the LDD regions of the high voltage region and the low voltage region.

3. The method of claim 1, wherein the first ion implant process is performed by implanting P ions and As ions.

4. The method of claim 1, wherein the second ion implant process is performed by implanting As ions.

5. A method for manufacturing a flash memory device, comprising the steps of:
forming gate electrode patterns on a semiconductor substrate on which a high voltage region and a low voltage region are defined;
forming a first mask pattern for simultaneously exposing the high voltage region and the low voltage region, and forming junction regions in the high voltage region and the low voltage region at the same time by performing a first ion implant process;
removing the first mask pattern for simultaneously exposing the high voltage region and the low voltage region, and forming spacers on each gate electrode pattern;
forming a second mask pattern for simultaneously exposing the high voltage region and the low voltage region; and
forming LDD regions in the junction region of the high voltage region and the junction region of the low voltage region at the same time by performing a second ion implant process;
forming an interlayer insulation film on the whole surface of the resulting structure; and
forming contact plugs contacting the LDD regions of the high voltage region and the low voltage region.

6. The method of claim 5, wherein the first ion implant process is performed by implanting P ions and As ions.

7. The method of claim 6, wherein the second ion implant process is performed by implanting As ions.
